(19) United States
(12) Patent Application Publication
(10) Pub. No.: US 2005/0224256 A1
(43) Pub. Date: Oct. 13, 2005

(54) Interlayer member used for producing multilayer wiring board and method of producing the same

(75) Inventors: Kenji Osawa, Tokyo (JP); Masayuki Osawa, Tokyo (JP); Tomokazu Shimada, Tokyo (JP); Kimitaka Endo, Tokyo (JP); Tomoo Iijima, Tokyo (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: NORTH CORPORATION, Tokyo (JP)

(21) Appl. No.: 11/085,108

(22) Filed: Mar. 22, 2005

(30) Foreign Application Priority Data
Mar. 26, 2004 (JP) 2004-093693

(51) Int. Cl. H05K 1/16; H01L 21/4763

(52) U.S. Cl. 174/260

(57) ABSTRACT

To increase the dimensional accuracy of an interlayer member used for producing a multilayer wiring board which is inserted between two wiring layers to establish interlayer insulation and interlayer electrical connection between the wiring layers, to thereby increase a layout density. A mask film is formed on a main surface of a sheet-like carrier layer. A metal column for interlayer connection is formed on the main surface of the carrier layer by plating a copper using the mask film as a mask. The mask film is removed. An interlayer insulating layer and a protective sheet are laminated on the main surface of the carrier layer in such a manner that the metal column for interlayer connection penetrates them. The interlayer insulating layer and the protective sheet are polished until the upper surface of the metal column for interlayer connection is exposed. Then, the carrier layer is removed. Furthermore, the protective sheet is removed.

### BACKGROUND OF THE INVENTION

1. Field of the Invention

The present invention relates to an interlayer member used for producing a multilayer wiring board by being inserted between two wiring layers to establish interlayer insulation and interlayer electrical connection between the wiring layers, and to a method of producing the same.

2. Description of the Related Art

The applicant of the present application has made various propositions in, for example, Japanese Patent Application No. 11-289277 (JP 2001-111189 A) and Japanese Patent Application No. 2003-132793 for a multilayer wiring board using a bump made of a metal such as copper as an interlayer connection means and for a method of producing the same.

Most of the techniques each employ a metal plate with a three-layer structure obtained by: placing an etching barrier layer (having a thickness of, for example, 1 μm) made of, for example, nickel on one surface of a metal layer (having a thickness of, for example, 10 μm) made of, for example, copper for forming a bump (projection); and placing a metal layer (having a thickness of, for example, 18 μm) made of, for example, copper for forming a wiring film on a surface of the etching barrier layer (surface opposite to the side of the metal layer for forming a bump).

Then, the metal layer for forming a bump is selectively etched to form metal bumps. After that, the etching barrier layer is removed by using each of the metal bumps as a mask. Then, a resin film for forming an interlayer insulating layer and a protective sheet are applied to the surface of the metal plate on which the bumps are formed, and the resin film and the protective sheet are laminated under pressure and heat. After that, the surface of the laminate is polished until the top faces of the metal bumps are exposed.

After the polishing, the protective sheet is peeled off, and a metal layer (having a thickness of, for example, 18 μm) made of, for example, copper for forming a wiring film is laminated on the surface of the polished side under pressure and heat. Thus, the top faces of the metal bumps are connected to the metal layer.

After that, the above respective metal layers for forming wiring films (the metal layer for forming a wiring film constituting the metal plate with a three-layer structure and the laminated metal layer for forming a wiring film) are selectively etched to form wiring films. As a result, interlayer insulation is established by the resin film, and a two-layer wiring board in which interlayer connection between the wiring films is established by the metal bumps is produced.

The wiring board may be singly used for mounting an IC or the like. Alternatively, the wiring board may be laminated on another wiring board, and the resultant having a multilayer structure may be used for mounting an IC or the like.

However, a technique of producing a multilayer wiring board without the use of such a metal plate with a three-layer structure has been developed partly because the production cost of a metal plate with a three-layer structure is expensive. FIGS. 10(A) to 10(D) are sectional diagrams showing a method of producing an interlayer member used for producing a multilayer wiring board to be used for such a production technique in step order. Hereinafter, the production method will be described with reference to the figures.

(A) As shown in FIG. 10(A), a product in which a metal foil b made of, for example, copper for forming a bump is laminated on a sheet-like carrier layer a made of, for example, a resin is prepared.

(B) Next, as shown in FIG. 10(B), the metal foil b for forming a bump is selectively etched to form metal bumps c, c, . . . . In the figure, only one metal bump c appears.

(C) Next, a sheet-like interlayer insulating layer d made of, for example, a polyimide resin and a cover layer e made of a resin are laminated on the surface of the carrier layer a on which the metal bumps c, c, . . . are formed in such a manner that the metal bumps c, c, . . . penetrate the layers d and e. After that, the cover layer e and the interlayer insulating layer d are polished until upper faces of the metal bumps c, c, are exposed. FIG. 10(D) shows a state after the polishing.

(D) Next, as shown in FIG. 10(D), the cover layer e is removed. Thus, an interlayer member f for producing a multilayer wiring board is produced.

The interlayer member f for producing a multilayer wiring board is used for producing a multilayer wiring board as shown in FIGS. 11(A) and 11(B) or in FIGS. 12(A) and 12(B).

First, a production method shown in FIGS. 11(A) and 11(B) will be described.

(A) As shown in FIG. 11(A), copper metal layers f′, f′ to serve as wiring layers are applied to both surfaces of the interlayer member f for producing a multilayer wiring board.

(B) Next, as shown in FIG. 11(B), the copper metal layers f′, f′ are laminated on the interlayer member f for producing a multilayer wiring board under heat and pressure for integration.

After that, although not shown, the copper metal layers f′, f′ are subjected to patterning by means of selective etching to form wiring films. Thus, a multilayer wiring board is produced.

Next, a production method shown in FIGS. 12(A) and 12(B) will be described.

(A) As shown in FIG. 12 (A), separately prepared multilayer wiring plates g, g are applied to both surfaces of the interlayer member f for producing a multilayer wiring board after the plates g, g are aligned with the member f in such a manner that wiring films j, j, . . . of the plates g, g match with the metal bumps c, c, . . . of the member f in positional relationship.

Reference symbol h denotes an interlayer insulating layer of each of the multilayer wiring plates g, g; i, a hole for interlayer connection; and j, a wiring layer made of, for example, copper formed on each surface of the interlayer insulating layer h. The wiring layers j, j are electrically interlayer-connected through a portion for filling in the hole i for interlayer connection.

(B) Next, as shown in FIG. 12(B), the multilayer wiring plates g, g are laminated on the interlayer member e for producing a multilayer wiring board under heat and pressure for integration in such a manner that the metal bumps c, c, . . . and the corresponding wiring layers j, j, . . . are connected to each other.

However, in the prior art shown in FIGS. 10(A) to 10(D), it has been difficult to increase the space (pitch) and dimensional accuracy of the metal bumps c, c, . . . , so it has been difficult to increase a layout density.

This is because of the following reasons. One reason is as follows. In the prior art, the formation of the metal bumps c, c, . . . is performed by the selective etching of the metal foil b for forming a bump on the carrier layer a. Therefore, a subtle error, side etching, and a formation error of an etching mask may occur depending on how an etchant contacts a surface to be treated. The other reason is as follows. Although the method provides high productivity, an etching resist involves side etching in the etching of copper. Therefore, a resist diameter considerably larger than a bump diameter to be formed is necessary, with the result that the pitch of bumps cannot be narrowed.

### SUMMARY OF THE INVENTION

The present invention has been made in order to solve the above problems, and an object of the present invention is to increase the dimensional accuracy of an interlayer member used for producing a multilayer wiring board which is inserted between two wiring layers to establish interlayer insulation and interlayer electrical connection between the wiring layers, to thereby increase a layout density.

An interlayer member used for producing a multilayer wiring board according to a first aspect of the present invention is inserted between two wiring layers to establish interlayer insulation and interlayer electrical connection between the wiring layers, and includes a sheet-like interlayer insulating layer perforated with a large number of holes for interlayer connection, in which: an inner peripheral surface of each of the holes for a metal column forms a substantially right angle relative to each main surface of the interlayer insulating layer; and a metal column for interlayer connection is inserted into each of the holes.

According to a second aspect of the present invention, in the interlayer member used for producing a multilayer wiring board according to the first aspect of the invention, at least one of an upper surface and a lower surface of the metal column for interlayer connection is flush with the main surface of the sheet-like interlayer insulating layer.

According to a third aspect of the present invention, in the interlayer member used for producing a multilayer wiring board according to the first aspect of the invention, at least one of the upper surface and the lower surface of the metal column for interlayer connection is depressed from the main surface of the sheet-like interlayer insulating layer.

According to a fourth aspect of the present invention, in the interlayer member used for producing a multilayer wiring board according to the first aspect of the invention, at least one of the upper surface and the lower surface of the metal column for interlayer connection protrudes from the holes for interlayer connection sheet-like interlayer insulating layer.

According to a fifth aspect of the present invention, in the interlayer member used for producing a multilayer wiring board according to the first aspect of the invention, the upper surface of the metal column for interlayer connection protrudes and spreads around in T-shape in section from the holes for interlayer connection.

According to a sixth aspect of the present invention, in the interlayer member used for producing a multilayer wiring board according to any one of the first to fifth aspects of the invention, a metal layer for enhancing junction made of a metal different from that of the metal column for interlayer connection is formed on at least one of the upper surface and the lower surface of the metal column for interlayer connection.

According to a seventh aspect of the present invention, in the interlayer member used for producing a multilayer wiring board according to the sixth aspect of the invention, the metal layer for enhancing junction is made of tin, palladium, silver, or gold.

According to an eighth aspect of the present invention, in the interlayer member used for producing a multilayer wiring board according to any one of the first to fifth aspects of the invention, the metal column for interlayer connection is movable in a thickness direction of the interlayer insulating layer.

According to a ninth aspect of the present invention, in the interlayer member used for producing a multilayer wiring board according to any one of the first to fifth aspects of the invention, the metal column for interlayer connection is made of copper.

According a tenth aspect of the present invention, a method of producing an interlayer member used for producing a multilayer wiring board includes the steps of: forming, on one main surface of a sheet-like carrier layer, a mask film having a negative pattern for a large number of metal columns for interlayer connection to be formed; forming metal columns for interlayer connection on the one main surface of the carrier layer by plating a metal using the mask film as a mask; removing the mask film; forming an interlayer insulating layer in a portion of the one main surface of the carrier layer where no metal column for interlayer connection is present; and peeling off the carrier layer.

According to an eleventh aspect of the present invention, in the method of producing an interlayer member used for producing a multilayer wiring board according to the tenth aspect of the invention, the step of forming an interlayer insulating layer is performed by: laminating at least a sheet-like interlayer insulating layer on the one main surface of the carrier layer; and polishing the interlayer insulating layer until upper surfaces of the respective metal columns for interlayer connection are exposed.

According to a twelfth aspect of the present invention, the method of producing an interlayer member used for producing a multilayer wiring board according to the eleventh aspect of the invention, further includes the steps of: laminating a sheet-like cover layer on an upper surface of the sheet-like interlayer insulating layer on the one main surface of the carrier layer; polishing the interlayer insulating layer and the cover layer until the upper surfaces of the respective metal columns for interlayer connection are exposed; and removing the cover layer.

According to a thirteenth aspect of the present invention, a method of producing an interlayer member used for producing a multilayer wiring board includes the steps of: forming, on one main surface of a sheet-like carrier layer, an interlayer insulating layer having a negative pattern for a large number of metal columns for interlayer connection to be formed; forming metal columns for interlayer connection on the one main surface of the carrier layer by plating a metal using the interlayer insulating layer as a mask; and peeling off the carrier layer.

According to a fourteenth aspect of the present invention, in the method of producing an interlayer member used for producing a multilayer wiring board according to any one of the tenth to thirteenth aspects of the invention, the same metal as that of each of the metal columns for interlayer connection is used for the carrier layer.

According to a fifteenth aspect of the present invention, in the method of producing an interlayer member used for producing a multilayer wiring board according to any one of the tenth to thirteenth aspects of the invention, a product obtained by laminating a metal layer made of the same metal as that of each of the metal columns for interlayer connection on an upper surface of a resin layer is used for the carrier layer.

According to a sixteenth aspect of the present invention, the method of producing an interlayer member used for producing a multilayer wiring board according to any one of the tenth to thirteenth aspects of the invention, further includes the steps of: forming an etching prevention film for preventing etching of the metal columns for interlayer connection on an upper surface of the carrier layer after the mask film or the interlayer insulating layer is formed and before the metal columns for interlayer connection are formed; and removing the etching prevention film simultaneously with or after removal of the carrier layer.

According to a seventeenth aspect of the present invention, a method of producing an interlayer member used for producing a multilayer wiring board includes the steps of: preparing, on a surface of a mold substrate at least one surface of which is flat, a mold for producing an interlayer member in which a mask film having a negative pattern for a large number of metal columns for interlayer connection to be formed is formed; forming metal columns for interlayer connection each of which is thicker than the mask film by plating on the flat surface of the mold substrate of the mold for producing an interlayer member; laminating a sheet-like interlayer insulating layer on the flat surface of the mold substrate in such a manner that portions of the metal columns for interlayer connection protruding from the mask film penetrate the interlayer insulating layer; and removing the interlayer insulating layer from the mold for producing an interlayer member together with the metal columns for interlayer connection that penetrate the interlayer insulating layer.

According to the interlayer member used for producing a multilayer wiring board according to the first aspect of the present invention, the metal column for interlayer connection is inserted into each of the holes for interlayer connection forming a substantially right angle relative to each main surface of the insulating layer. Therefore, the metal column can be formed by plating using the mask film as a mask without the occurrence of side etching.

Therefore, the dimensional accuracy of the metal column for interlayer connection can be increased, and hence the layout density can be increased.

According to the interlayer member used for producing a multilayer wiring board according to the second aspect of the present invention, at least one of the upper surface and the lower surface of the metal column for interlayer connection is flush with the main surface of the sheet-like interlayer insulating layer. Therefore, when a wiring plate which is to be laminated on at least one surface of the interlayer member used for producing a multilayer wiring board and which has a wiring film on its surface is laminated under pressure and heat, the wiring film and the interlayer member used for producing a multilayer wiring board can be satisfactorily connected by the applied pressure.

According to the interlayer member used for producing a multilayer wiring board according to the third aspect of the present invention, in the interlayer member used for producing a multilayer wiring board the first aspect of the invention, at least one of the upper surface and the lower surface of the metal column for interlayer connection is depressed from the main surface of the sheet-like interlayer insulating layer. Therefore, when a wiring plate which is to be laminated on at least one surface of the interlayer member used for producing a multilayer wiring board and which has a thick wiring film on its surface is laminated under pressure and heat, the wiring film and the interlayer member used for producing a multilayer wiring board can be satisfactorily connected by the applied pressure.

According to the interlayer member used for producing a multilayer wiring board according to the fourth aspect of the present invention, at least one of the upper surface and the lower surface of the metal column for interlayer connection protrudes from the main surface of the sheet-like interlayer insulating layer. Therefore, when a wiring plate which has a thin wiring film on its surface is laminated under pressure and heat, the wiring film and the interlayer member used for producing a multilayer wiring board can be satisfactorily connected by the applied pressure.

According to the interlayer member used for producing a multilayer wiring board according to the fifth aspect of the present invention, the upper surface of the metal column for interlayer connection protrudes and spreads around in T-shape in section from the holes for interlayer connection of the sheet-like interlayer insulating layer to a periphery of the main surface. Therefore, a wiring plate having a wiring film and the interlayer member used for producing a multilayer wiring board can be laminated in such a manner that an upper portion of the metal column for interlayer connection and the wiring film can be satisfactorily connected.

According to the interlayer member used for producing a multilayer wiring board according to the sixth aspect of the present invention, a metal layer for enhancing junction made of a metal different from that of the metal column for interlayer connection is formed on at least one of the upper surface and the lower surface of the metal column for interlayer connection. Therefore, a wiring plate having a wiring film and the interlayer member used for producing a multilayer wiring board can be laminated in such a manner that the surface of the metal column for interlayer connection on which the metal layer for enhancing junction is formed and the wiring film can be satisfactorily connected.

According to the interlayer member used for producing a multilayer wiring board according to the seventh aspect of the present invention, the metal layer for enhancing junction is made of tin, palladium, silver, or gold. Therefore, good connection can be established between the metal column for interlayer connection and another wiring film through the metal layer for enhancing junction, and a resistance parasitic on the connection portion can be reduced.

According to the interlayer member used for producing a multilayer wiring board according to the eighth aspect of the present invention, the metal column for interlayer connection is movable in a thickness direction of the interlayer insulating layer. Therefore, when multilayer wiring plates are laminated on both surfaces of the interlayer member used for producing a multilayer wiring board, a positional relationship of the metal column for interlayer connection with respect to the interlayer insulating layers of the multilayer wiring plates and the interlayer insulating layer of the interlayer member used for producing a multilayer wiring board in a thickness direction can be balanced.

According to the interlayer member used for producing a multilayer wiring board according to the ninth aspect of the present invention, the metal column for interlayer connection is made of copper. Therefore, interlayer connection can be established with a low resistance without an extremely high cost.

According to the method of producing an interlayer member used for producing a multilayer wiring board according to the tenth aspect of the present invention, the metal columns for interlayer connection are formed by plating a metal using the mask film as a mask. Therefore, even when a metal layer is selectively etched to form a metal column for interlayer connection, none of a subtle error, side etching, and a formation error of an etching mask occurs independent of how an etchant contacts a surface to be treated.

According to the method of producing an interlayer member used for producing a multilayer wiring board according to the eleventh aspect of the present invention, the step of forming an interlayer insulating layer is performed by: laminating a sheet-like interlayer insulating layer on the carrier layer; and polishing the interlayer insulating layer until the upper surfaces of the respective metal columns for interlayer connection are exposed. Therefore, the upper surfaces of the metal columns for interlayer connection can be brought into contact with a wiring film of a wiring plate or a metal layer for forming a wiring film not belonging to the interlayer member used for producing a multilayer wiring board.

According to the method of producing an interlayer member used for producing a multilayer wiring board according to twelfth aspect of the present invention, a sheet-like cover is overlapped on the upper surface of the interlayer insulating layer, hereafter the interlayer insulating layer and the cover are polished until the upper surface of the metal column is exposed, then the cover is removed, so that the area around the upper surface of the insulating layer is kept clean to manufacture easily the structure where the metal column is projected from the insulating layer.

According to the method of producing an interlayer member used for producing a multilayer wiring board according to the thirteenth aspect of the present invention, increasing effects on the dimensional accuracy and a formation density exerted by the method of producing an interlayer member used for producing a multilayer wiring board according to the eleventh aspect of the invention can be obtained. In addition, the insulating layer used as a mask at the time of formation of metal columns for interlayer connection by selective plating is directly used as the interlayer insulating layer, so the following effects can be obtained.

That is, there is no need to newly form an interlayer insulating layer after the mask film has been formed and used. In addition, there is no need to polish the surface of each metal column for interlayer connection. As a result, the number of production steps can be reduced.

Furthermore, polishing is not needed. As a result, connectivity does not deteriorate owing to the resin constituting the interlayer insulating layer or the like remaining in a flaw developing on the surface of a metal column owing to the polishing.

According to the method of producing an interlayer member used for producing a multilayer wiring board according to the fourteenth aspect of the present invention, the same metal as that of each of the metal columns for interlayer connection is used for the carrier layer. Therefore, a good metal column for interlayer connection can be formed by plating smoothly from the surface of the carrier layer.

According to the method of producing an interlayer member used for producing a multilayer wiring board according to the fifteenth aspect of the present invention, a product obtained by laminating a metal layer made of the same metal as that of each of the metal columns for interlayer connection on an upper surface of a resin layer is used for the carrier layer. Therefore, a good metal column for interlayer connection can be formed by plating smoothly from the surface of the carrier layer.

In addition, the resin layer is placed on the lower surface of the metal layer, and a mechanical strength necessary for the carrier layer can be obtained by means of the resin layer. Therefore, the metal layer can be thin, and hence the amount of the metal layer to be used can be reduced.

According to the method of producing an interlayer member used for producing a multilayer wiring board according to the sixteenth aspect of the present invention, an etching prevention film for preventing etching of the metal columns for interlayer connection is formed on the upper surface of the carrier layer after the mask film or the interlayer insulating layer is formed and before the metal columns for interlayer connection are formed. Therefore, the etching prevention film can prevent the metal columns for interlayer connection from being etched at the time of removal of the carrier layer.

Therefore, the carrier layer can be removed without etching the lower surface of the metal column for interlayer connection.

According to the method of producing an interlayer member used for producing a multilayer wiring board according to the seventeenth aspect of the present invention, metal columns for interlayer connection each of which is thicker than the mask film are formed by plating on the flat surface of the mold for producing an interlayer member, a sheet-like interlayer insulating layer is laminated in such a manner that portions of the metal columns for interlayer connection protruding from the mask film penetrate the interlayer insulating layer, and the interlayer insulating layer is removed from the mold for producing an interlayer member together with the metal columns for interlayer connection that penetrate the interlayer insulating layer. Therefore, an interlayer member used for producing a multilayer wiring board can be easily produced sequentially through repeated use of a single mold for producing an interlayer member, so a significant reduction in production cost can be achieved.

### BRIEF DESCRIPTION OF THE DRAWINGS

In the accompanying drawings:

FIGS. 1(A) to 1(F) are sectional diagrams showing a method of producing an interlayer member used for producing a multilayer wiring board according to Example 1 of the present invention in step order;

FIGS. 2(A) to 2(E) are sectional diagrams showing a method of producing an interlayer member used for producing a multilayer wiring board according to Example 2 of the present invention in step order;

FIGS. 3(A) to 3(D) are sectional diagrams showing a method of producing an interlayer member used for producing a multilayer wiring board according to Example 3 of the present invention in step order;

FIG. 4 is a sectional diagram showing a modified example of an interlayer member used for producing a multilayer wiring board obtained by increasing the number of steps of the production method shown in FIGS. 3(A) to 3(D) to depress the surface of a metal column for interlayer connection from the surface of an interlayer insulating layer;

FIGS. 5(A) to 5(D) are sectional diagrams showing a method of producing an interlayer member used for producing a multilayer wiring board according to Example 4 of the present invention in step order;

FIGS. 6(A) to 6(E) are sectional diagrams showing a method of producing an interlayer member used for producing a multilayer wiring board according to Example 5 of the present invention in step order;

FIG. 7 is a sectional diagram showing a structure example of an interlayer insulating layer with a three-layer structure of the interlayer member used for producing a multilayer wiring board of the present invention;

FIGS. 8(A) and 8(B) are sectional diagrams showing an example of lamination of metal layers for forming wiring layers on an interlayer member used for producing a multilayer wiring board;

FIGS. 9(A) and 9(B) are sectional diagrams showing an example of lamination of wiring plates having wiring films on an interlayer member used for producing a multilayer wiring board;

FIGS. 10(A) to 10(D) are sectional diagrams showing a conventional method of producing an interlayer member used for producing a multilayer wiring board in step order;

FIGS. 11(A) and 11(B) are sectional diagrams showing an example of a method of producing a multilayer wiring board by laminating metal layers for forming wiring films on a conventional interlayer member used for producing a multilayer wiring board in step order; and

FIGS. 12(A) and 12(B) are sectional diagrams showing an example of a method of producing a multilayer wiring board by laminating wiring plates on a conventional interlayer member used for producing a multilayer wiring board in step order.

### DESCRIPTION OF THE PREFERRED EXAMPLES

The interlayer member used for producing a multilayer wiring board of the present invention is basically such that a sheet-like interlayer insulating layer is perforated with a large number of holes for interlayer connection, an inner peripheral surface of each of the holes for interlayer connection forms a substantially right angle relative to each main surface of the insulating layer, and a metal column for interlayer connection is inserted into each of the holes for interlayer connection. The metal column for interlayer connection is preferably made of copper.

With regard to the relationship between the~upper surface or the lower surface of the metal column for interlayer connection and the main surface of the sheet-like interlayer insulating layer, at least one of the upper surface and the lower surface may be preferably flush with the main surface, may be preferably depressed from the main surface, or may preferably protrude from the main surface depending on, for example, the thickness of the metal layer for forming a wiring film or of, for example, the metal layer or the wiring layer of the wiring plate having a wiring film, and a material for the interlayer member used for producing a multilayer wiring board itself or for the interlayer insulating layer of the wiring plate.

In addition, the upper surface of the metal column for interlayer connection may be protruded and spread in T-shape in section from the holes for interlayer connection of the sheet-like interlayer insulating layer to a periphery of the main surface.

Furthermore, a metal layer for enhancing junction made of a metal different from that of the metal column for interlayer connection may be formed on at least one of the upper surface and the lower surface of the metal column for interlayer connection to reduce a resistance parasitic on a connection portion between the metal column for interlayer connection and another wiring film through the metal layer for enhancing junction. Tin, zinc, palladium, platinum, silver, or gold is preferably used for the metal layer for enhancing junction.

In addition, the metal column for interlayer connection may be movable in a thickness direction of the interlayer insulating layer.

With this configuration, when multilayer wiring plates are laminated on both surfaces of the interlayer member used for producing a multilayer wiring board, a positional relationship of the metal column for interlayer connection with respect to the interlayer insulating layers of the multilayer wiring plates and the interlayer insulating layer of the interlayer member used for producing a multilayer wiring board in a thickness direction can be balanced.

The method of producing an interlayer member used for producing a multilayer wiring board of the present invention is basically classified into the following three modes. A first basic mode includes: forming a mask film on one main surface of a sheet-like carrier layer; forming metal columns for interlayer connection on the one main surface by plating a metal using the mask film as a mask; removing the mask film; forming an interlayer insulating layer in a portion of the carrier layer where no metal column for interlayer connection is present; and removing the carrier layer. However, the formation of the interlayer insulating layer is suitably performed by: laminating at least a sheet-like interlayer insulating layer on the one main surface of the carrier layer; and polishing the interlayer insulating layer until the upper surface of the respective metal column for interlayer connection is exposed.

In addition, a sheet-like cover layer may be laminated on the upper surface of the sheet-like interlayer insulating layer, then the interlayer insulating layer and the cover layer may be polished until the upper surfaces of the respective metal columns for interlayer connection are exposed, and then the cover layer may be removed.

A second basic mode involves direct use of the insulating layer, which is used as a mask at the time of formation of metal columns for interlayer connection by selective plating, as the interlayer insulating layer. Therefore, there is no need to newly form an interlayer insulating layer after the mask film has been formed and used. In addition, there is no need to polish the surface of each metal column for interlayer connection. As a result, the number of production steps can be reduced. Furthermore, polishing is not needed. As a result, connectivity does not deteriorate owing to the resin remaining in a flaw developed on the surface of a metal column owing to the polishing.

A third basic mode includes: forming metal columns for interlayer connection each of which is thicker than the mask film by plating on the flat surface of the mold substrate of the mold for producing an interlayer member; laminating a sheet-like interlayer insulating layer on the flat surface of the mold substrate in such a manner that portions of the metal columns for interlayer connection protruding from the mask film penetrate the interlayer insulating layer; and removing the interlayer insulating layer from the mold for producing an interlayer member together with the metal columns for interlayer connection that penetrate the interlayer insulating layer.

### EXAMPLE 1

Hereinafter, the present invention will be described in detail by way of examples shown in the figures.

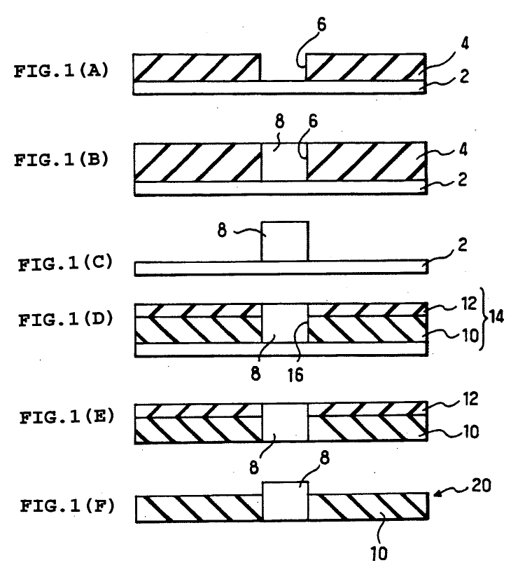

FIGS. 1(A) to 1(F) are sectional diagrams showing a method of producing an interlayer member used for producing a multilayer wiring board according to Example 1 of the present invention in step order.

(A) First, a sheet-like carrier layer 2 (having a thickness of, for example, several micrometers to several hundreds of micrometers) made of, for example, copper is prepared. A photosensitive mask film 4 is applied to and formed on the surface of the carrier layer 2. After that, the photosensitive mask film 4 is subjected to exposure and development treatment to produce a mask film having a negative pattern for a large number of metal columns for interlayer connection (8, 8, . . . ) to be formed. FIG. 1(A) shows a state after the exposure and the development treatment. Reference numerals 7 6, 6, . . . each denotes a hole for interlayer connection of the mask film 4.

(B) Next, the surface of the carrier layer 2 made of copper on which the mask film 4 is formed is plated with, for example, copper by using the mask film 4 as a mask to form the metal columns 8, 8, for interlayer connection. FIG. 1(B) shows a state after the metal columns 8, 8, . . . for interlayer connection (only one metal column 8 for interlayer connection appears in the figure) have been formed. The plating is copper plating using the carrier layer 2 made of copper as a substrate, so the metal columns 8, 8, . . . for interlayer connection having good film properties can be formed smoothly by, for example, electrolytic plating.

(C) Next, as shown in FIG. 1(C), the mask film 4 made of the photosensitive resist is removed.

(D) Next, a laminated sheet 14 composed of a sheet-like interlayer insulating layer 10 and a protective sheet 12 laminated on the upper surface of the layer is laminated in such a manner that the metal columns 8, 8, . . . for interlayer connection penetrate the laminated sheet. After that, the laminated sheet 14 is polished until the upper surfaces of the metal columns 8, 8, . . . for interlayer connection are exposed. FIG. 1(D) shows a state after the polishing. Reference numerals 16, 16, . . . denote holes for interlayer connection of the interlayer insulating layer 10 formed when the metal columns 8, 8, . . . for interlayer connection penetrate the laminated sheet.

(E) Next, as shown in FIG. 1(E), the carrier layer 2 is removed by etching.

(F) Next, as shown in FIG. 1(F), the laminated sheet 14 is removed. Thus, one interlayer member 20 for producing a multilayer wiring board is produced.

According to such an example, metal columns for interlayer connection are formed by plating a metal using the mask film as a mask. Therefore, even when a metal layer is selectively etched, none of a subtle error, side etching, and a formation error of an etching mask occurs independent of how an etchant contacts a surface to be treated.

In this example, after the completion of the step shown in FIG. 1(A), an etching barrier layer (etching prevention film) made of nickel may be formed on the exposed surfaces of the metal columns 8, 8, . . . for interlayer connection by plating before the formation of the metal columns 8, 8, . . . for interlayer connection. This is because the etching barrier layer can prevent the lower surfaces of the metal columns 8, 8, . . . for interlayer connection from being etched when the carrier layer 2 is removed by etching.

In addition, after the completion of the step shown in FIG. 1(D), etching for removing the etching barrier layer may be performed. This is because of the following reason. When the etching barrier layer completes its role as an etching prevention film of preventing the lower surfaces of the metal columns 8, 8, . . . for interlayer connection from being etched, the necessity for the layer is eliminated. Removing the layer can improve connectivity between each of the metal columns 8, 8, . . . for interlayer connection and the wiring layer or the metal layer for forming a wiring layer to be connected to it.

When a material having a small specific resistance such as aluminum or tin is used for the etching barrier layer instead of nickel, the etching barrier layer can be also used as a metal layer for enhancing junction. As a result, the removing step is not needed. By the way, a technique of forming the etching barrier layer is used in a second example (Example 2) to be described next.

Although not shown, the rear surface of the carrier layer 2 maybe coated with an insulating film for preventing plating adhesion.

### EXAMPLE 2

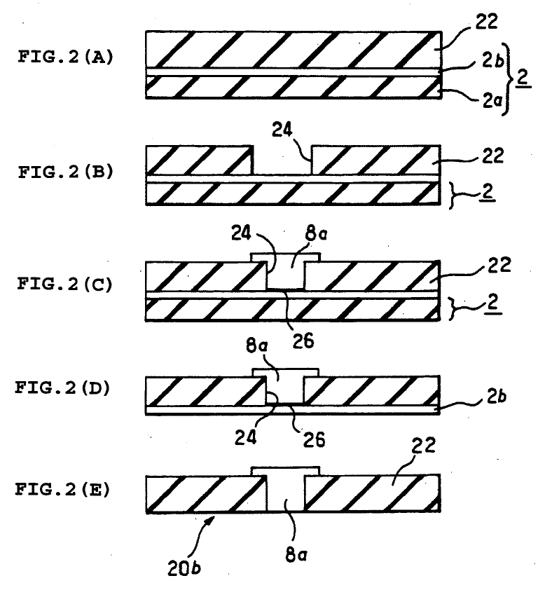

FIGS. 2(A) to 2(E) are sectional diagrams showing a method of producing an interlayer member used for producing a multilayer wiring board according to Example 2 of the present invention in step order.

(A) First, a carrier layer 2 made of resin coated copper (RCC) is prepared. An interlayer insulating layer 22 made of, for example, thermoplastic polyimide is formed on the surface of the carrier layer 2. FIG. 2(A) shows a state after the interlayer insulating layer 22 has been formed.

A photosensitive one may be used as the interlayer insulating layer 22. In this case, the formation of holes for interlayer connection (24, 24, . . . ) to be performed later can be performed by exposure and development.

Reference symbol 2a denotes a resin film constituting a lower layer of the carrier layer 2. The resin film has a thickness necessary for ensuring the mechanical strength of the carrier layer 2 necessary for ensuring the ease of production, for example, a thickness of several tens of micrometers to several hundreds of micrometers. In addition, reference symbol 2b denotes a copper layer constituting an upper layer of the carrier layer 2. The copper layer has a thickness necessary for functioning as a substrate of plating for forming the metal columns 8, 8, . . . for interlayer connection, for example, a thickness of 2 μm to 6 μm.

A product obtained by laminating the copper layer 2b having a thickness of about 2 μm to 6 μm on the resin film 2a has been used as the carrier layer 2. It is also possible to use a product obtained by laminating an aluminum layer or a tin layer instead of the copper layer 2b on the resin film 2a.

(B) Next, the interlayer insulating layer 22 is subjected to laser processing by means of laser light to form the holes 24, 24, . . . for interlayer connection. FIG. 2(B) shows a state after the holes 24, 24, . . . for interlayer connection have been formed. When a photosensitive one is used as the interlayer insulating layer 22, the holes 24, 24, . . . for interlayer connection are formed by exposure and development.

(C) Next, an etching barrier layer 26 (having a thickness of, for example, 2 μm to 6 μm) made of, for example, nickel is formed on the surface of the carrier layer 2 by using the interlayer insulating layer 22 as a mask.

After that, metal columns 8a, 8a, . . . for interlayer connection are formed by plating, for example, copper. FIG. 2(C) shows a state after the metal columns 8a, 8a, . . . for interlayer connection have been formed.

In this example, copper is appropriately plated at a thickness greater than that of the interlayer insulating layer 22 so that each of the metal columns 8a, 8a, . . . for interlayer connection protrudes in T-shape in section from the holes for interlayer connection of the interlayer insulating layer to a periphery of the main surface. This action is intended to improve connectivity between the upper surface of each of the metal columns 8a, 8a, . . . for interlayer connection and the wiring layer or the metal layer for forming a wiring layer to be connected to it.

(D) Next, as shown in FIG. 2(D), the resin film 2a of the carrier layer 2 is removed by peeling.

(E) Next, the copper layer 2b remaining in the carrier layer 2 is removed by etching, and then the etching barrier layer 26 is removed. Thus, an interlayer member 20b for producing a multilayer wiring board is produced. FIG. 2(E) shows a state after the etching barrier layer 26 has been removed.

The reason why the etching barrier layer is formed is the same as that of Example 1. In addition, as in Example 1, a material having a small specific resistance such as aluminum or tin may be used for the etching barrier layer instead of nickel, and in this case, the etching barrier layer can be also used as a metal layer for enhancing junction, so the removing step is not needed.

According to this example, the layer 22 having photosensitivity to be used as a mask at the time of formation of the metal columns 8a, 8a, . . . for interlayer connection by selective plating is directly used as the interlayer insulating layer. As a result, there is no need to newly form an interlayer insulating layer by removing the mask film after the mask film has been formed and used as a mask for selective plating. In addition, there is no need to polish the interlayer insulating layer until the upper surfaces of the metal columns 8a, 8a, . . . are exposed, so the number of steps for producing an interlayer member used for producing a multilayer wiring board can be reduced.

Furthermore, there is no need to expose the upper surfaces of the metal columns 8a, 8a, . . . by polishing. As a result, connectivity does not deteriorate owing to leavings of the resin constituting the interlayer insulating layer remaining as residues in flaws developing on the upper surfaces of the metal columns 8a, 8a, . . . owing to the polishing.

### EXAMPLE 3

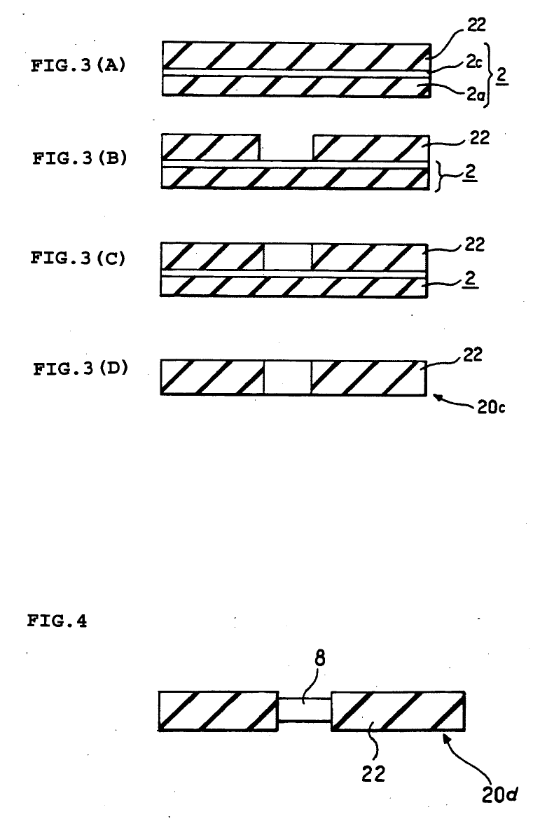

FIGS. 3(A) to 3(D) are sectional diagrams showing a method of producing an interlayer member used for producing a multilayer wiring board according to Example 3 of the present invention in step order.

(A) First, a releasable metal layer 2c (having a thickness of, for example, 2 μm to 6 μm) made of stainless steel (SUS), nickel, or the like is laminated on the upper surface of a resin film 2a. Furthermore, the surface of the releasable metal layer 2c is subjected to potassium permanganate treatment (this treatment is not indispensable) to prepare a carrier layer 2. Then, an interlayer insulating layer 22 made of, for example, thermoplastic polyimide is formed on the surface of the carrier layer 2. FIG. 3(A) shows a state where the interlayer insulating layer 22 has been formed.

Any one of various metals other than stainless steel and nickel can be used for the releasable metal layer 2c to be laminated on the upper surface of the resin film 2a. For example, a product obtained by: forming a copper layer; and plating the surface of the copper layer with another metal such as nickel serving as an etching barrier against copper etching can be used.

(B) Next, the interlayer insulating layer 22 is subjected to laser processing to form holes 24, 24, . . . for interlayer connection. FIG. 3(B) shows a state where the holes 24, 24, . . . for interlayer connection have been formed. It is needless to say that one having photosensitivity may be used as the interlayer insulating layer 22 and may be subjected to exposure and development treatment to form the holes 24, 24, . . . for interlayer connection.

(C) Next, the surface of the carrier layer 2 is plated with, for example, copper by using the interlayer insulating layer 22 as a mask to form metal columns 8, 8, . . . for interlayer connection. FIG. 3(C) shows a state where the metal columns 8, 8, . . . for interlayer connection have been formed.

In this example, copper is plated at the same height as that of the upper surface of the interlayer insulating layer 22.

(D) Next, as shown in FIG. 3(D), the carrier layer 2 composed of the resin film 2a and the releasable metal layer 2c is removed by peeling. Thus, an interlayer member 20c for producing a multilayer wiring board is produced.

After the completion of the step shown in FIG. 3(D), in the interlayer member 20c for producing a multilayer wiring board, surface layer portions of both surfaces of the metal column 8 for interlayer connection may be etched in such a manner that the metal column 8 for interlayer connection is depressed from each main surface of the interlayer insulating layer 22. Reference symbol 20d denotes an interlayer member used for producing a multilayer wiring board thus obtained.

This action is performed for eliminating the following possibility. In the case where wiring films of the wiring plates to be laminated on both surfaces of the interlayer member 20c for producing a multilayer wiring board greatly protrude from the interlayer insulating layers of the wiring plates, the metal column 8 for interlayer connection is excessively thick if both surfaces of the metal column 8 for interlayer connection are flush with (on the same planes as those of) both main surfaces of the interlayer insulating layer 22. As a result, the sum of the thicknesses of: the interlayer member 20c for producing a multilayer wiring board; and the interlayer insulating layers of the wiring plates may be unbalanced. In such a case, it is desirable to use the interlayer member 20d for producing a multilayer wiring board shown in FIG. 4.

### EXAMPLE 4

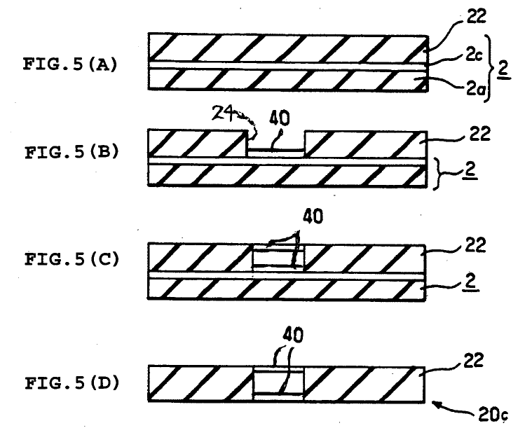

FIGS. 5(A) to 5(D) are sectional diagrams showing a method of producing an interlayer member used for producing a multilayer wiring board according to Example 4 of the present invention in step order.

As shown in FIG. 5(D), in this example, metal layers 40, 40 for enhancing junction made of metal are formed on both the upper and lower surfaces of a metal column 8 for interlayer connection.

(A) First, a releasable metal layer 2c (having a thickness of, for example, 2 μm to 6 μm) made of stainless steel (SUS), nickel, or the like is laminated on the upper surface of a resin film 2a. Furthermore, the surface of the releasable metal layer 2c is subjected to potassium permanganate treatment (this treatment is not indispensable) to prepare a carrier layer 2. Then, an interlayer insulating layer 22 made of, for example, thermoplastic polyimide is formed on the surface of the carrier layer 2. FIG. 5(A) shows a state where the interlayer insulating layer 22 has been formed.

As in Example 3 shown in FIGS. 3(A) to (D), any one of various metals other than stainless steel and nickel can be used for the releasable metal layer 2c to be laminated on the upper surface of the resin film 2a.

(B) Next, the interlayer insulating layer 22 is subjected to laser processing to form holes 24, 24, . . . for interlayer connection. After that, a metal layer 40 for enhancing junction is formed by plating using the interlayer insulating layer 22 as a mask. A suitable material for the metal layer 40 for enhancing junction is, for example, tin, palladium, gold, or silver. In addition, the thickness of the metal layer 40 for enhancing junction is preferably, for example, in the range of 3 μm to 6 μm when tin is used, while it is preferably in the range of 0.5 μm to 2 μm when a noble metal such as palladium, gold, or silver is used. FIG. 5(B) shows a state where the metal layer 40 for enhancing junction has been formed. It is needless to say that one having photosensitivity may be used as the interlayer insulating layer 22 and may be subjected to exposure and development treatment to form the holes 24, 24, . . . for interlayer connection.

(C) Next the surface of the metal layer 40 for enhancing junction on the carrier layer 2 is plated with, for example, copper by using the interlayer insulating layer 22 as a mask to form metal columns 8, 8, . . . for interlayer connection. Next, another metal plate 40 for enhancing junction is formed by plating using the interlayer insulating layer 22 as a mask.

The material for the other metal layer 40 for enhancing junction may be the same as that for the metal layer 40 for enhancing junction formed in the step shown in FIG. 5(B). In addition, the thickness of the other layer may be the same as that of the layer formed in the step shown in FIG. 5(B). That is, the thickness of the other layer is preferably, for example, in the range of 3 μm to 6 μm when tin is used, while it is preferably in the range of 0.5 μm to 2 μm when a noble metal such as palladium, gold, or silver is used. FIG. 5(C) shows a state where the upper metal layer 40 for enhancing junction has been formed.

In this example, the height of the upper surface of the upper metal layer 40 for enhancing junction is the same as that of the upper surface of the interlayer insulating layer 22.

(D) Next, as shown in FIG. 5(D), the carrier layer 2 composed of the resin film 2a and the releasable metal layer 2c is removed by peeling. Thus, an interlayer member 20e for producing a multilayer wiring board is produced.

### EXAMPLE 5

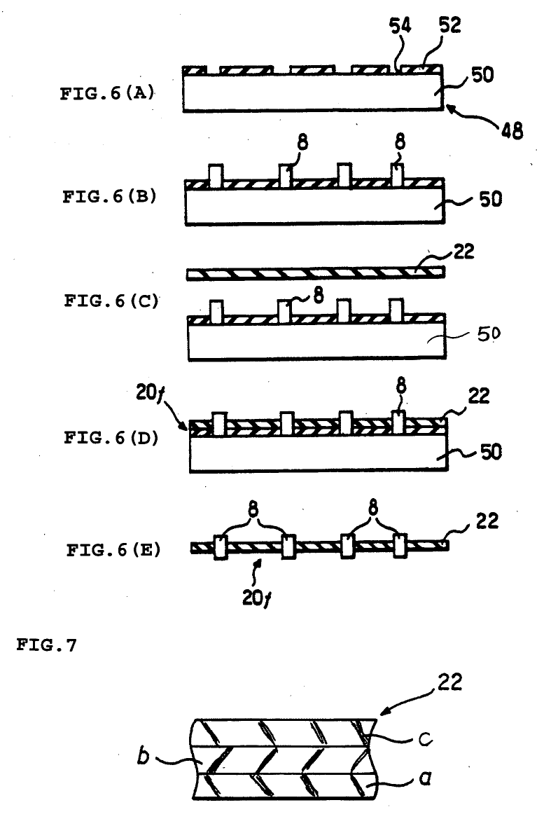

FIGS. 6(A) to 6(E) are sectional diagrams showing a method of producing an interlayer member used for producing a multilayer wiring board according to Example 5 of the present invention in step order.

(A) In this example, a mold 48 for producing an interlayer member shown in FIG. 6(A) is used. The mold 48 is obtained by fixing a mask film 52 for forming a metal column for interlayer connection to the surface of a mold substrate 50 at least an upper main surface of which is flat. Reference numerals 54, 54, . . . denote holes for interlayer connection through which metal columns for interlayer connection (8, 8, . . . ) are formed by plating.

The mold substrate 50 is preferably made of a metal such as stainless steel so that it can be subjected to electrolytic plating. A metal is preferably used for the mold substrate 50 because a metal column is easily peeled off from the mold substrate when the surface of the substrate is subjected to chromate treatment (treatment with CrO₃).

Although the mask film 52 may be made of an organic substance or an inorganic substance, it is preferably made of a metal. This is because processability allowing the film to be formed with high accuracy, strong fixability to the mold substrate 50 allowing the film to be used repeatedly (on a semipermanent basis), hardness for preventing the film from being easily worn or destroyed, or the like is needed.

In addition, it is preferable that a portion other than a portion where plating is precipitated be coated with a durable inorganic or organic insulator to prevent plating from being precipitated and the surface be coated with Teflon (registered trademark) or the like to allow the interlayer insulating layer to be released later.

(B) Next, as shown in FIG. 6(B), the metal columns 8, 8, . . . for interlayer connection are formed by electroplating on the surface of the mold substrate 50 on which the mask film 52 is formed. In this case, each of the metal columns 8, 8, . . . for interlayer connection must be formed to protrude from the surface of the mask film 52 by a height equal to or greater than the thickness of an interlayer insulating layer of an interlayer member used for producing a multilayer wiring board to be formed.

(C) Next, as shown in FIG. 6(C), an insulating sheet 22 to serve as the interlayer insulating layer of the interlayer member used for producing a multilayer wiring board to be formed is allowed to face the mold substrate 50.

(D) Next, as shown in FIG. 6(D), the insulating sheet 22 is laminated on the mold substrate 50 in such a manner that the metal columns 8, 8, . . . for interlayer connection penetrate the sheet. Thus, an interlayer member 20f for producing a multilayer wiring board is formed on the mold 48.

(E) After that, as shown in FIG. 6(E), the interlayer member 20f for producing a multilayer wiring board is separated from the mold 48.

In this example, the mold 48 shown in each of FIGS. 6(A) to (D) is repeatedly used for producing the interlayer member 20f for producing a multilayer wiring board.

Therefore, according to this example, interlayer members for producing multilayer wiring boards can be successively produced through repeated use of one mold for producing an interlayer member, so a significant reduction in production cost can be achieved.

In this example, the interlayer member 20f for producing a multilayer wiring board to be produced has a structure in which the metal columns 8, 8, . . . for interlayer connection protrude from the lower surface of the interlayer insulating layer 22. The metal columns may protrude from the upper surface of the insulating layer, may be flush with the upper surface, or may be depressed from the upper surface.

By the way, each of the interlayer insulating layers 22 of the interlayer members 20 and 20a to 20f for producing multilayer wiring boards of the above respective examples is preferably made of a polyimide resin or thermoplastic polyimide (for example, TPI: thermoplastic polyimide), or a thermosetting resin sheet or thermoplastic resin sheet in a B-stage state such as a liquid crystal polymer, and has a thickness of preferably in the range of 25 μm to 35 μm.

In addition, in each of the above examples, the interlayer insulating layer 22 has been of a monolayer structure. However, the layer may be of a multilayer structure (such as a three-layer structure).

FIG. 7 shows an example of the structure of an interlayer insulating layer 22 with a three-layer structure.

In the figure, reference symbol a denotes a lower layer of the interlayer insulating layer 22. The lower layer is made of a thermoplastic polyimide resin and has a thickness preferably in the range of 5 μm to 20 μm. Reference symbol b denotes an intermediate layer of the interlayer insulating layer 22. The intermediate layer is made of non-thermoplastic polyimide and has a thickness preferably in the range of 10 μm to 14 μm, for example, 12 μm. Reference symbol c denotes an upper layer of the interlayer insulating layer 22. The upper layer is made of a thermoplastic polyimide resin and has a thickness preferably in the range of 5 μm to 20 μm.

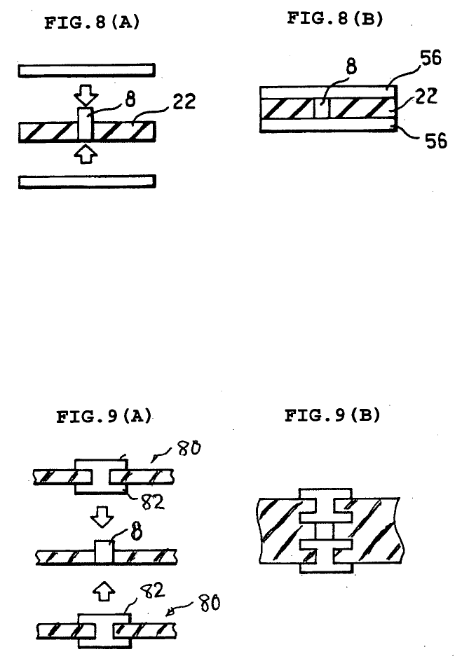

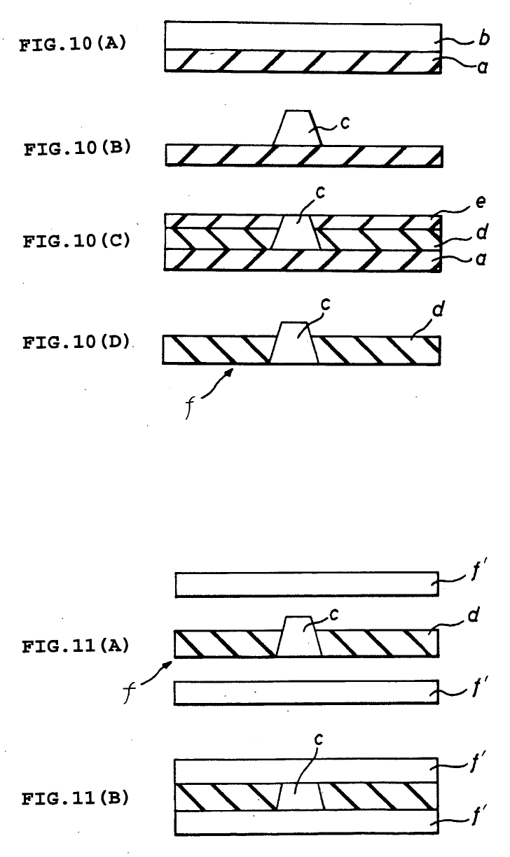

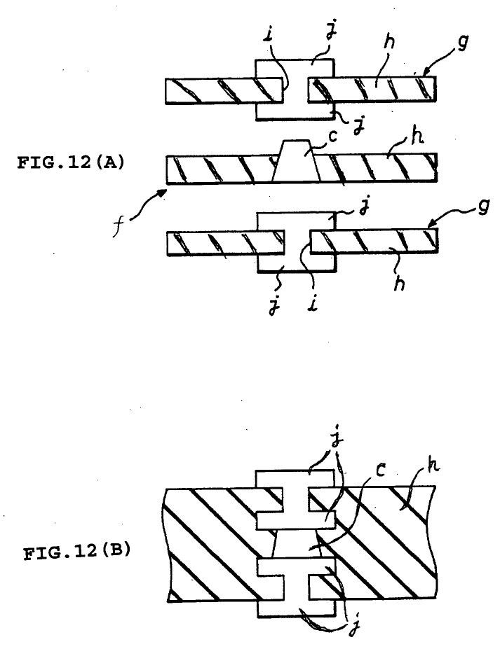

When copper foils 56, 56 serving as metal layers for forming wiring films are laminated on both the upper and lower surfaces of an interlayer member used for producing a multilayer wiring board such as the member 20 as shown in FIGS. 8(A) and 8(B), each of the lower layer a and the upper layer c is preferably made of TPI (or a liquid crystal polymer) having a thickness of 5 μm and the intermediate layer b is preferably made of polyimide having a thickness of 12 μm.

Next, when wiring plates 80, 80 each having a wiring film 82 protruding from an interlayer insulating layer are laminated on both the upper and lower surfaces of an interlayer member used for producing a multilayer wiring board such as the member 20 as shown in FIGS. 9(A) and 9(B), each of the lower layer a and the upper layer c is preferably thicker than that in the case shown in FIGS. 8(A) and 8(B) because the interlayer insulating layer 22 must absorb the thickness of the wiring film 82. Specifically, each of the lower layer a and the upper layer c is made of a thermoplastic polyimide resin having a thickness in the range of 20 μm to 35 μm. The intermediate layer b may be preferably made of non-thermoplastic polyimide having a thickness of 12 μm as in the case shown in FIGS. 8(A) and 8(B).

In addition, in each of the examples, the metal column 8 for interlayer connection preferably has movability in the thickness direction of the interlayer insulating layer 22. The term “movability” refers to property with which the metal column 8 for interlayer connection, which does not leave the interlayer insulating layer 22 in ordinary cases, can move in the thickness direction of the interlayer insulating layer 22 when the column receives the pressure applied at the time of lamination.

If the metal column for interlayer connection has the movability, when multilayer wiring plates are laminated on both surfaces of, for example, the interlayer member 20 for producing a multilayer wiring board, a positional relationship of the metal column for interlayer connection with respect to the interlayer insulating layers of the multilayer wiring plates and the interlayer insulating layer of the interlayer member used for producing a multilayer wiring board in a thickness direction can be balanced.

In addition, the movability can be enhanced when a material having a low affinity for the metal column for interlayer connection is selected as a material for the interlayer insulating layer. However, if the movability is excessively strong, the metal column for interlayer connection may be released from the interlayer insulating layer with a small force. It is necessary to select a material having an affinity capable of providing movability that does not lead to such a phenomenon.

It has been confirmed that, in the case where the interlayer insulating layer 22 structured as shown in FIG. 7 is used, the metal column 8 for interlayer connection has appropriate movability with respect to the interlayer member 20 for producing multilayer wiring board when a material having a low affinity for the metal constituting the metal column is selected as a material for the interlayer insulating layer.

As described above, the present invention can be implemented in any one of various modes.

The present invention can be generally applied to: an interlayer member used for producing a multilayer wiring board which is inserted between two wiring layers to establish interlayer insulation and interlayer electrical connection between the wiring layers; and a method of producing the same.

1. An interlayer member used for producing a multilayer wiring board which is inserted between two wiring layers to establish interlayer insulation and interlayer electrical connection between the wiring layers, comprising:
a sheet-like interlayer insulating layer perforated with a large number of holes for interlayer connection, wherein:
an inner peripheral surface of each of the holes for interlayer connection forms a substantially right angle relative to each main surface of the interlayer insulating layer; and
a metal column for interlayer connection is inserted into each of the holes for interlayer connection.

2. An interlayer member used for producing a multilayer wiring board according to claim 1, wherein at least one of an upper surface and a lower surface of the metal column for interlayer connection is flush with the main surface of the sheet-like interlayer insulating layer.

3. An interlayer member used for producing a multilayer wiring board according to claim 1, wherein at least one of the upper surface and the lower surface of the metal column for interlayer connection is depressed from the main surface of the sheet-like interlayer insulating layer.

4. An interlayer member used for producing a multilayer wiring board according to claim 1, wherein at least one of the upper surface and the lower surface of the metal column for interlayer connection protrudes from the main surface of the sheet-like interlayer insulating layer.

5. An interlayer member used for producing a multilayer wiring board according to claim 1, wherein the upper surface of the metal column for interlayer connection protrudes and spreads around in T-shape in section from the holes for interlayer connection.

6. An interlayer member used for producing a multilayer wiring board according to any one of claims 1, 2, 3, 4, and 5, wherein a metal layer for enhancing junction made of a metal different from that of the metal column for interlayer connection is formed on at least one of the upper surface and the lower surface of the metal column for interlayer connection.

7. An interlayer member used for producing a multilayer wiring board according to claim 6, wherein the metal layer for enhancing junction is made of one of tin, palladium, silver, and gold.

8. An interlayer member used for producing a multilayer wiring board according to any one of claims 1, 2, 3, 4 and 5, wherein the metal column for interlayer connection is movable in a thickness direction of the interlayer insulating layer.

9. An interlayer member used for producing a multilayer wiring board according to any one of claims 1, 2, 3, 4 and 5, wherein the metal column for interlayer connection is made of copper.

10. A method of producing an interlayer member used for producing a multilayer wiring board, comprising the steps of:
forming, on one main surface of a sheet-like carrier layer, a mask film having a negative pattern for a large number of metal columns for interlayer connection to be formed;
forming metal columns for interlayer connection on the one main surface of the carrier layer by plating a metal using the mask film as a mask;
removing the mask film;
forming an interlayer insulating layer in a portion of the one main surface of the carrier layer where none of the metal column for interlayer connection is present; and
peeling off the carrier layer.

11. A method of producing an interlayer member used for producing a multilayer wiring board according to claim 10, wherein the step of forming the interlayer insulating layer is performed by:
laminating at least a sheet-like interlayer insulating layer on the one main surface of the carrier layer; and
polishing the interlayer insulating layer until upper surfaces of the respective metal columns for interlayer connection are exposed.

12. A method of producing an interlayer member used for producing a multilayer wiring board according to claim 11, further comprising the steps of:
laminating a sheet-like cover layer on an upper surface of the sheet-like interlayer insulating layer on the one main surface of the carrier layer;
polishing the interlayer insulating layer and the cover layer until the upper surfaces of the respective metal columns for interlayer connection are exposed; and
removing the cover layer.

13. A method of producing an interlayer member used for producing a multilayer wiring board, further comprising the steps of:
forming, on one main surface of a sheet-like carrier layer, an interlayer insulating layer having a negative pattern for a large number of metal columns for interlayer connection to be formed;
forming metal columns for interlayer connection on the one main surface of the carrier layer by plating a metal using the interlayer insulating layer as a mask; and
peeling off the carrier layer.

14. A method of producing an interlayer member used for producing a multilayer wiring board according to any one of claims 10, 11, 12, and 13, wherein the same metal as that of each of the metal columns for interlayer connection is used for the carrier layer.

15. A method of producing an interlayer member used for producing a multilayer wiring board according to any one of claims 10, 11, 12, and 13, wherein a product obtained by laminating a metal layer made of a metal which is the same as or different from that of each of the metal columns for interlayer connection on an upper surface of a resin layer is used for the carrier layer.

16. A method of producing an interlayer member used for producing a multilayer wiring board according to any one of claims 10, 11, 12 and 13, further comprising the steps of:
forming an etching prevention film for preventing etching of the metal columns for interlayer connection on an upper surface of the carrier layer after one of the mask film and the interlayer insulating layer is formed and before the metal columns for interlayer connection are formed; and
removing the etching prevention film simultaneously with or after removal of the carrier layer.

17. A method of producing an interlayer member used for producing a multilayer wiring board, comprising the steps of:
preparing, on a surface of a mold substrate at least one surface of which is flat, a mold for producing an interlayer member in which a mask film having a negative pattern for a large number of metal columns for interlayer connection to be formed is formed;
forming metal columns for interlayer connection each of which is thicker than the mask film by plating on the flat surface of the mold substrate of the mold for producing an interlayer member;
laminating a sheet-like interlayer insulating layer on the flat surface of the mold substrate in such a manner that portions of the metal columns for interlayer connection protruding from the mask film penetrate the interlayer insulating layer; and
removing the interlayer insulating layer from the mold for producing an interlayer member together with the metal columns for interlayer connection that penetrate the interlayer insulating layer.
